(19) United States
(12) Patent Application Publication
(10) Pub. No.: US 2025/0300086 A1
(43) Pub. Date: Sep. 25, 2025

(54) OPTICAL AND ELECTRICAL GLASS INTERPOSER WITH EMBEDDED BRIDGE

(71) Applicant: Intel Corporation, Santa Clara, CA (US)

(72) Inventors: Jeremy D. Ecton, Gilbert, AZ (US); Benjamin T. Duong, Phoenix, AZ (US); Tarek A. Ibrahim, Mesa, AZ (US); Srinivas Venkata Ramanuja Pietambaram, Chandler, AZ (US); Brandon Christian Marin, Gilbert, AZ (US); Gang Duan, Chandler, AZ (US); Bohan Shan, Chandler, AZ (US)

(73) Assignee: Intel Corporation, Santa Clara, CA (US)

(21) Appl. No.: 18/615,585

(22) Filed: Mar. 25, 2024

(51) Int. Cl. H01L 23/538; H01L 21/48; H01L 23/00; H01L 25/00; H01L 25/18

(52) U.S. Cl. CPC H01L 23/5386; H01L 21/486; H01L 25/18; H01L 25/50; H01L 23/5384; H01L 24/05; H01L 24/08; H01L 24/80; H01L 2224/05647; H01L 2224/08225; H01L 2224/08235; H01L 2224/80357; H01L 2224/80379; H01L 2224/80447; H01L 2224/80486; H01L 2224/8049; H01L 2224/80896; H01L 2924/0544; H01L 2924/07025

(57) ABSTRACT

Semiconductor devices and systems with optical and electrical interposers, and methods of forming the same, are disclosed herein. In one example, a semiconductor device includes a glass substrate and a bridge die embedded in the glass substrate, where the glass substrate includes one or more optical waveguides and the bridge die includes an interconnect to electrically couple multiple integrated circuit dies.

### BACKGROUND

High-speed optical interconnects are crucial to meet the continuously increasing data rate demands of modern data centers and computing systems. For example, traditional computing components (e.g., processors, accelerators, FPGAs, switches, memory/storage, other ASIC nodes) can be packaged with optical interfaces to enable them to communicate over high-speed optical interconnects rather than traditional electrical interconnects. Existing optical packaging solutions suffer from various shortcomings, however, including complex assembly processes, high costs, low yield, and poor performance. As a result, existing optical packaging solutions are unable to satisfy the increasing demand for smaller form factors with higher levels of integration and better performance.

### BRIEF DESCRIPTION OF THE DRAWINGS

FIG. 1 illustrates an optical interface with an optical/electrical glass interposer.

FIGS. 2A-H illustrate a process flow for forming an optical interface with an optical/electrical glass interposer.

FIGS. 3A-D illustrate various example embodiments of integrated circuit (IC) packages with an optical/electrical glass interposer.

FIG. 4 illustrates a process flow for forming an IC package with an optical/electrical glass interposer.

FIGS. 5A-B illustrate examples of hybrid dielectric and metal bonds.

FIG. 6 illustrates a cross-sectional view of an interconnect bridge embedded within a substrate.

FIG. 7 illustrates a top view of a wafer and dies that may be included in a microelectronic assembly.

FIG. 8 illustrates a cross-sectional side view of an integrated circuit device that may be included in a microelectronic assembly.

FIG. 9 illustrates a cross-sectional side view of an integrated circuit device assembly that may include a microelectronic assembly.

FIG. 10 illustrates a block diagram of an example electronic device that may include a microelectronic assembly.

### DETAILED DESCRIPTION

High-speed optical interconnects are crucial to meet the continuously increasing data rate demands of modern data centers and computing systems. For example, traditional computing components (e.g., processors, accelerators, FPGAs, switches, memory/storage, other ASIC nodes) can be packaged with optical interfaces to enable them to communicate over high-speed optical interconnects rather than traditional electrical interconnects.

Optical packaging can be challenging, however, as the demand for miniaturization of form factors and increased levels of integration for higher performance are driving the need for more sophisticated packaging approaches in the semiconductor industry. For example, die partitioning is an approach that typically involves partitioning the functionality of a monolithic die into smaller chiplets which are then packaged together. While die partitioning enables small form factors and high performance without the yield issues of other methods, it also requires fine die-to-die (D2D) interconnections between chiplets, which can be challenging. In some cases, D2D interconnections may be implemented using embedded multi-die interconnect bridge (EMIB) technology, which is a low cost and simple 2.5D packaging approach that enables very-high-density interconnects between heterogeneous dies on a single package. In particular, instead of using a large and expensive silicon interposer with through-silicon vias (TSVs), a small silicon bridge chip may be embedded in the package to provide high-density die-to-die connections only where needed. Standard flip-chip assembly can be used for robust power delivery and high-speed signal routing directly from the chip to the package substrate. Further, incorporating through-silicon vias (TSVs) into conventional EMIB technology, referred to as EMIB-T technology, enables power to be routed from the bottom of the package substrate up through the bridge—instead of through the package substrate to the top of the bridge—thus reducing the number of routing layers required in the package substrate, which increases yield. However, assembling an EMIB-T bridge within a package substrate can be challenging due to a complex embedding process, which typically requires underfill below the bridge in a deep cavity within the package substrate.

Accordingly, this disclosure presents embodiments of an optical/electrical glass interposer with an embedded interconnect bridge, along with semiconductor packages, devices, and systems incorporating the same, and methods of forming the foregoing. In some embodiments, for example, the interposer may include a glass substrate with (i) an embedded multi-die interconnect bridge within a cavity of the glass substrate for transmission of electrical signals between multiple integrated circuit (IC) dies (e.g., XPUs and other electronic integrated circuits (EICs), photonic integrated circuits (PICs), high-bandwidth memory (HBM)) and (ii) optical waveguides in the glass substrate for transmission of optical signals (e.g., from a PIC to a fiber array unit (FAU)). Further, in some embodiments, the embedded interconnect bridge may include through-bridge vias—such as through-silicon vias (TSVs) for a bridge implemented on a silicon substrate—to enable power and/or electrical signals to be routed directly up through the bridge (e.g., through the bottom of the bridge to the top).

The described embodiments provide various advantages. For example, the glass interposer architecture enables transmission of both optical and electrical signals. Due to the good dimensional stability and low total thickness variation (TTV) of glass, the glass interposer is very well suited to accommodate the stringent flatness requirements associated with hybrid bonding of the electrical components (e.g., PIC, EIC, XPU) for better electrical performance and tighter bump pitch. The inclusion of TSVs (or the equivalent) in the embedded multi-die interconnect bridge enables power and/or signal routing to the IC dies directly through the bridge, which reduces the number of routing layers in the package substrate and results in higher yield. Further, since the multi-die interconnect bridge is embedded in the glass interposer rather than the package substrate, high-cost components are disaggregated from the package substrate, and the complex embedding process required to embed a TSV-enabled bridge deep within the package substrate is avoided, which simplifies the assembly process.

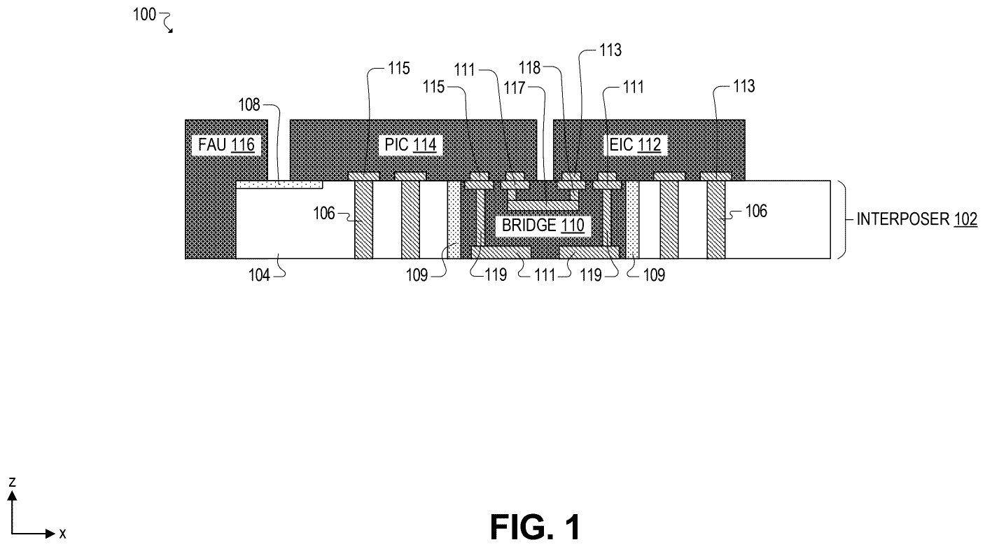

FIG. 1 illustrates a cross-section view of an optical interface 100 with an optical/electrical glass interposer 102 in accordance with certain embodiments. In the illustrated embodiment, the optical interface 100 includes an electronic integrated circuit (EIC) 112, a photonic integrated circuit (PIC) 114, a fiber array unit (FAU) 116 (e.g., an array of optical fibers), and an optical/electrical glass interposer 102. The EIC 112 is used to control the PIC 114, and the PIC 114 is used to send and receive optical signals over the FAU 116. Moreover, the EIC 112, the PIC 114, and the FAU 116 are attached to the optical/electrical glass interposer 102, which provides optical and/or electrical routing for the respective components. For example, the interposer 102 includes optical waveguides 108 to route optical signals between the PIC 114 and FAU 116. The interposer 102 also includes through-glass vias (TGVs) 106, and an embedded multi-die interconnect bridge (EMIB) 110 with traces 117/vias 118 and through-silicon vias 119 (also referred to herein as “EMIB-T”), to route power and/or electrical signals to, from, and/or between the EIC 112 and the PIC 114.

In the illustrated embodiment, the optical/electrical glass interposer 102 includes a glass substrate 104, optical waveguides 108 on the top surface of the glass substrate 104, TGVs 106 extending through the glass substrate 104 (e.g., between the top/bottom surfaces of the glass substrate 104), and an interconnect bridge 110 embedded within a cavity of the glass substrate 104.

The optical waveguides 108 on the surface of the glass substrate 104 enable optical signals to be routed/transmitted between the PIC 114 and the FAU 116. In particular, both the PIC 114 and the FAU 116 are optically coupled to the optical waveguides 108, and in turn, they are optically coupled to each other via the optical waveguides 108. In some embodiments, the PIC 114, the FAU 116, and/or the interposer 102 may include mating/alignment features (not shown) such as V-grooves to optically couple the PIC 114 and the FAU 116 to the optical waveguides 108 on the interposer 102 (e.g., either directly or indirectly via an optical coupler/connector).

The interconnect bridge 110 may be an integrated circuit die, also referred to herein as a bridge die 110, patterned with conductive contacts 111, traces 117, and vias 118, 119, which collectively form an electrical interconnect. For example, the conductive contacts 111 may be patterned on the top and/or bottom surfaces of the bridge 110 and may be electrically coupled to each other by the traces 117 and vias 118, 119. In the illustrated embodiment, some of the vias are blind/buried vias 118 that extend partially through the bridge 110, and others are through-bridge vias (TBVs) 119 that extend through the entire bridge 110 (e.g., between conductive contacts 111 on the top/bottom surfaces of the bridge 110). In some embodiments, for example, the bridge 110 may be patterned on a silicon substrate, and the through-bridge vias 119 may be through-silicon vias (TSVs) extending through the silicon substrate.

Moreover, the bridge 110 is embedded within a cavity of the glass substrate 104 using an adhesive material 109, such as a mold, epoxy, and/or dielectric material. In the illustrated embodiment, the bridge cavity is bottomless and extends all the way through the glass substrate 104, and the bridge 110 is designed with substantially the same thickness as the glass substrate 104, such that when the bridge 110 is embedded in the cavity of the glass substrate 104, the top and bottom surfaces of the bridge 110 are flush with the top and bottom surfaces of the glass substrate 104, respectively.

This design allows the EIC 112 and the PIC 114 to be attached to the top of both the glass substrate 104 and the embedded bridge 110, thus electrically coupling the EIC 112 and the PIC 114 directly to the glass substrate 104 and the bridge 110. In some embodiments, for example, the EIC 112 and the PIC 114 may be hybrid bonded on top of the glass substrate 104 and the bridge 110, such that the conductive contacts 113, 115 on the EIC 112 and the PIC 114 are electrically coupled to TGVs 106 in the glass substrate 104 and conductive contacts 111 on the bridge 110.

In this manner, the embedded interconnect bridge 110 and the through-glass vias (TGVs) 106 in the glass substrate 104 enable power and/or electrical signals to be routed/transmitted to, from, and/or between the EIC 112 and the PIC 114. For example, the EIC 112 and the PIC 114 are electrically coupled to each other through the traces 117 and vias 118 in the embedded interconnect bridge 110. Further, the EIC 112 and the PIC 114 may be electrically coupled to other components—such as a package substrate (e.g., to supply power and/or route signals to other IC dies or packages)—through the TGVs 106 in the glass substrate 104 and/or through the TSVs 119 in the bridge 110.

For simplicity, only some instances of the elements shown in optical interface 100 are labeled with reference numerals. Further, it should be appreciated that optical interface 100 is merely presented as an example. In other embodiments, certain components may be omitted, added, rearranged, modified, or combined.

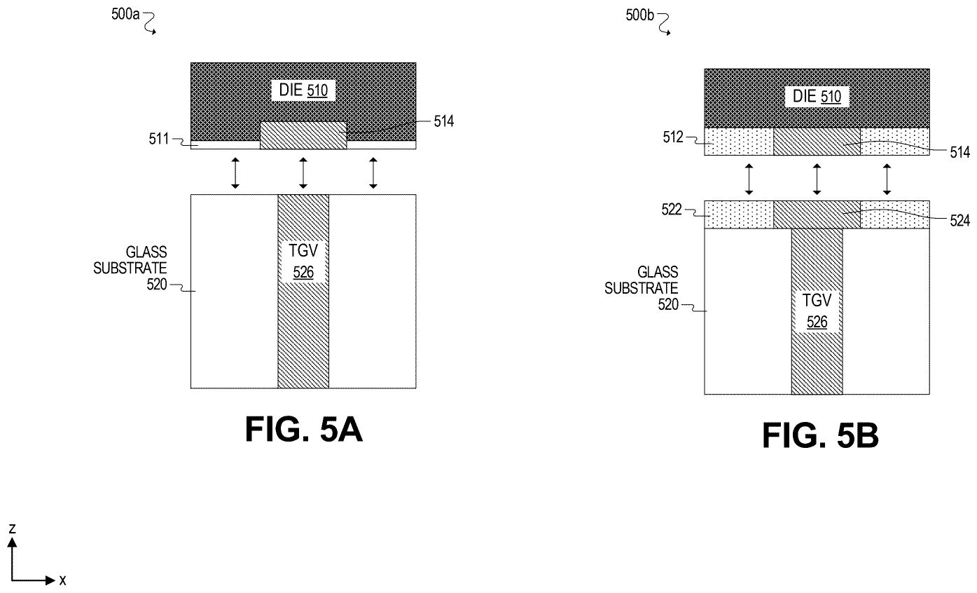

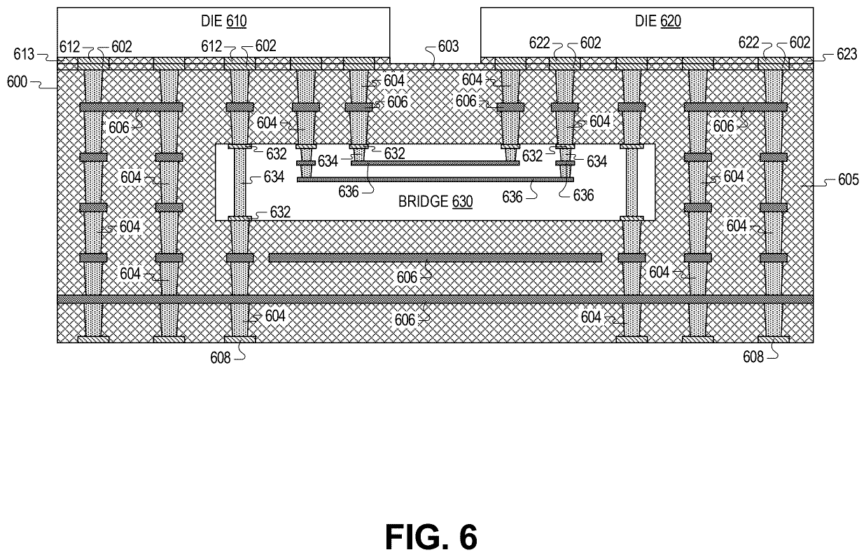

In various embodiments, for example, the glass substrate 104 may include a glass core and optionally additional layers (not shown) on the glass core, such as dielectric layer(s) containing conductive contacts on the top and/or bottom surfaces of the glass substrate 104 to enable hybrid bonding (e.g., as shown and described with respect to substrates 520, 600 of FIGS. 5B, 6), dielectric and metallization layers that form conductive traces and vias for additional electrical routing, etc.

In various embodiments, the optical waveguides 108 may be on the surface of the glass substrate 104 and/or within the glass substrate 104. For example, the waveguides 108 may be partially on the surface of the glass substrate 104 and partially within the glass substrate 104. Alternatively, some waveguides 108 may be on the surface of the glass substrate 104 and others may be within the glass substrate 104.

Further, in various embodiments, the optical waveguides 108 may be optically coupled to a component other than an FAU 116 (e.g., another optical co-package, PIC, etc.).

The bridge 110 may be formed on any suitable type of substrate, including, but not limited to, a silicon substrate. Moreover, the bridge 110 may include any type and/or combination of vias, including blind vias, buried vias, and/or through-bridge vias (e.g., through-silicon vias (TSVs) for a bridge implemented on a silicon substrate). Further, while the bridge 110 has substantially the same thickness as the glass substrate 104 and is embedded flush within the glass substrate 104 in the illustrated embodiment, in other embodiments the bridge 110 may be less thick than the glass substrate 104 and its top and/or bottom surfaces may be fully embedded within the glass substrate 104 (e.g., as shown and described with respect to bridge 630 in FIG. 6).

The EIC 112 may include any suitable electronic components and circuitry for controlling the PIC 114, such as drivers, transimpedance amplifiers (TIA), carrier phase recovery (CPR) circuitry, clock/data recovery (CDR) circuitry, serializers/deserializers, equalizers, samplers, and so forth. Moreover, while the EIC 112 is used to control the PIC 114 in the illustrated embodiment, the EIC 112 may be any type of electronic integrated circuit in other embodiments (e.g., XPU, processor, memory, etc.).

The PIC 114 may include any suitable photonic components and circuitry for sending and receiving optical signals (e.g., over the FAU 116), such as laser diodes (LD)/modulators (LD-MOD) (e.g., for transmitting optical signals), photodiodes (PD) (e.g., for receiving optical signals), waveguides, optical couplers, collimation/refocusing lenses, reflection mirrors, and so forth.

The FAU 116 may include any type, number, and/or arrangement of optical waveguides, including, but not limited to, glass fibers. The other end of the FAU 116 may be optically coupled to other components (not shown), which enables the PIC 114 to send and receive optical signals to and from those components, such as other computing components that are part of the same device or system as optical interface 100 (e.g., processors, XPUs, network interface controllers (NICs), storage, memory, I/O devices, other integrated circuits), an external device or system, a switch, an optical connector, a fiber cable, and so forth.

The bridge 110, EIC 112, and PIC 114 (and optionally the glass substrate 104 in some embodiments) may include any suitable type and/or combination of conductive contacts 111, 113, 115, including, without limitation, conductive pads, bumps/micro-bumps, balls, etc. Moreover, the conductive contacts 111, 113, 115 may be made of any suitable type and/or combination of conductive materials, including, without limitation, metal, copper, titanium, and/or solder. Further, in various embodiments, the respective electrical components of optical interface 100 may be attached and/or electrically coupled using any suitable interconnect mechanism, including, without limitation, hybrid dielectric/metal bonding and/or solder bonding. In embodiments where the PIC 114 is solder bonded to the optical waveguides 108, there may be a gap between the PIC 114 and the optical waveguides 108, and thus an optical coupler may be inserted between the PIC 114 and the waveguides 108 to optically couple those components together.

In the illustrated embodiment, for example, the bridge 110, EIC 112, and PIC 114 include hybrid bonding pads 111, 113, 115. Moreover, the EIC 112 and the PIC 114 are hybrid bonded to the glass substrate 104 and the bridge 110 to form hybrid dielectric-to-dielectric and metal-to-metal bonds between the respective components (e.g., as described in connection with FIGS. 5A-B, 6). For example, a dielectric layer on the face of the EIC 112 and the PIC 114, respectively, may be bonded to dielectric layers on the face of the glass substrate 104 and the bridge 110, and the pads 113, 115 on the EIC 112 and the PIC 114, respectively, may be bonded to the TGVs 106 in the glass substrate 104 and the pads 111 on the bridge 110.

In the illustrated embodiment, the interposer 102 includes through-glass vias (TGVs) 106 in the glass substrate 104 and through-bridge vias (TBVs) 119 in the bridge 110. In other embodiments, however, the interposer 102 may only include the TGVs 106 in the glass substrate 102 or the TBVs 119 in the bridge 110 (but not both).

In various embodiments, the glass substrate 104, bridge 110, and EIC 112/PIC 114 may be implemented with some or all aspects of the substrate 600, bridge 630, and IC dies 610/620 shown and described in connection with FIG. 6, respectively (e.g., including the hybrid bonding aspects).

In some embodiments, the optical interface 100 may include various thermal management solutions above and/or between the EIC 112 and PIC 114 (e.g., heat sink, integrated heat spreader, thermal interface materials (TIMs)).

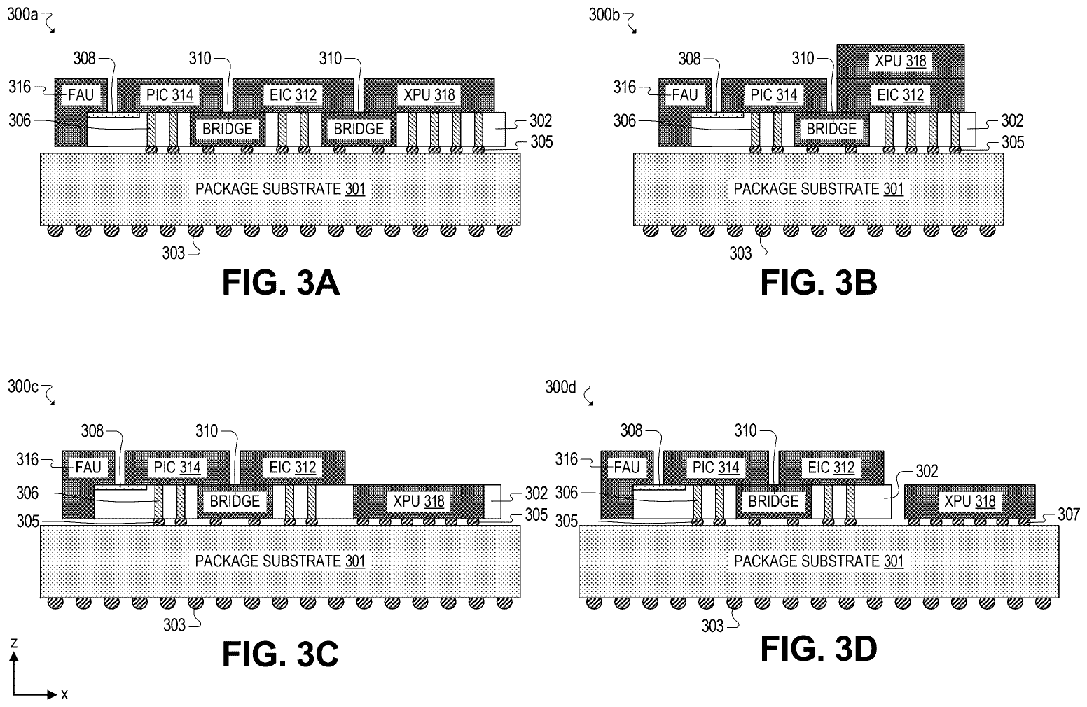

In some embodiments, the optical interface 100 may be attached to a package substrate (e.g., as shown and described in connection with optical packages 300a-d of FIGS. 3A-D). For example, the bottom of the TGVs 106 in the glass substrate 104 and the conductive contacts 111 on the bottom of the bridge 110 may be electrically coupled to conductive contacts on the package substrate (e.g., via solder bond or hybrid bond). Further, in some embodiments, other computing components may be co-packaged with optical interface 100 (e.g., processors, CPUs, XPUs, memory, storage, NICs, I/O devices), either on the same or different package substrate.

Moreover, various embodiments may include any number, combination, or arrangement of optical and/or electrical components, including multiple EICs, PICs, FAUs, and/or optical/electrical interposers (e.g., for higher bandwidth and/or redundancy), optical connectors, optical couplers, optical ferrules, bridges, XPUs or other computing components, substrates, substrate cavities, conductive contacts, conductive traces, vias, integrated circuit packages, and so forth.

These variations also apply to the other embodiments described throughout this disclosure (e.g., optical packages 300a-d of FIGS. 3A-D).

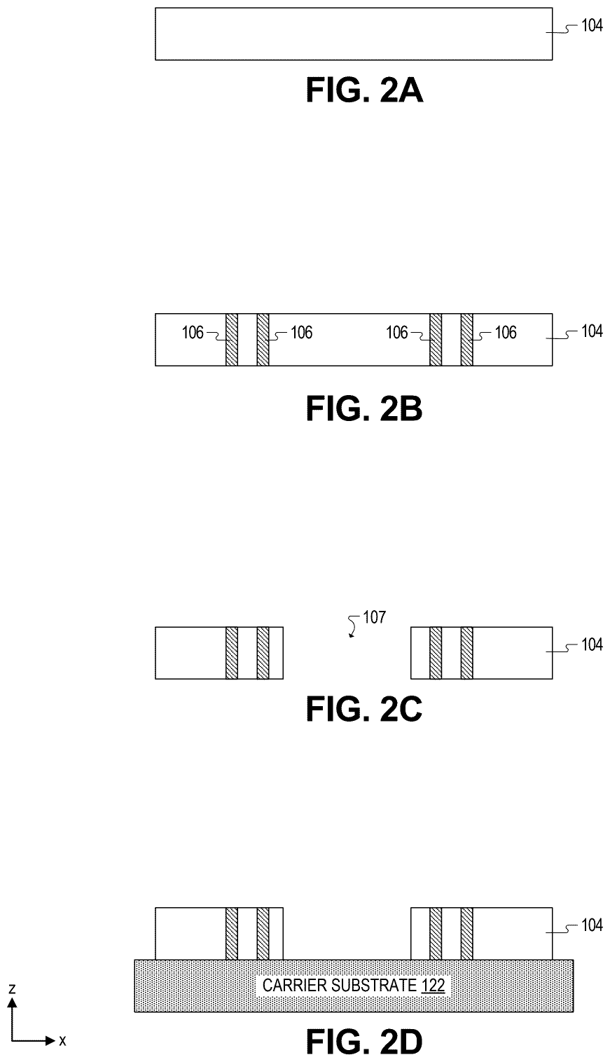

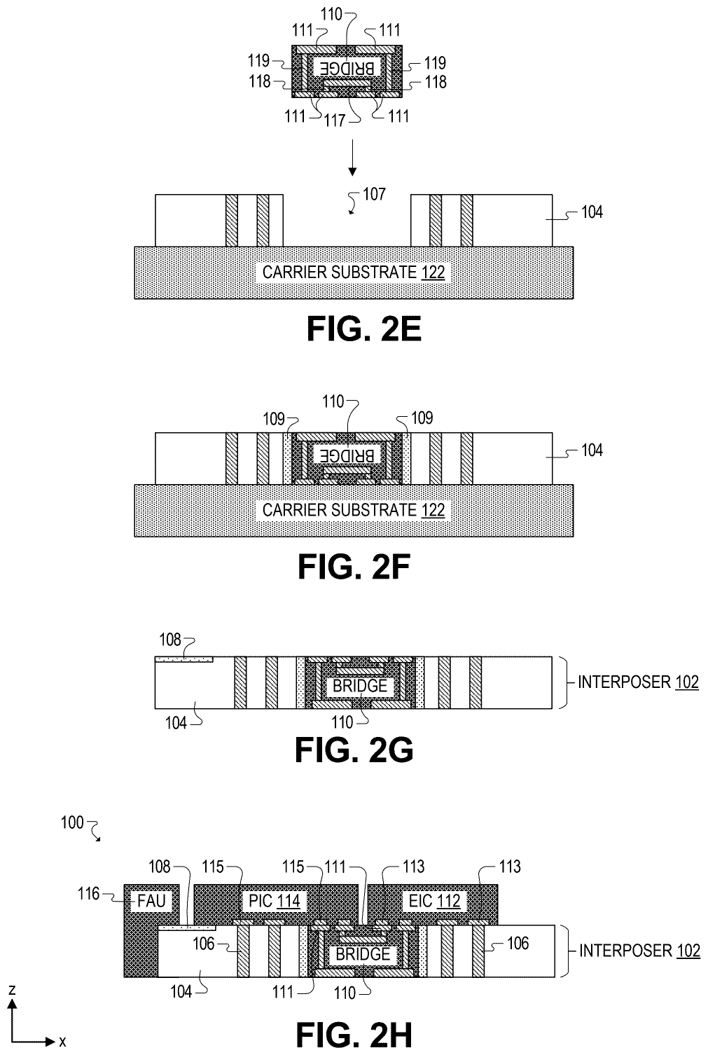

FIGS. 2A-H illustrate an example process flow for forming an optical interface with an optical/electrical glass interposer. The illustrated process flow is shown using cross-sectional/profile views taken in the X-Z plane. In the illustrated example, the process flow is used to form the optical interface 100 of FIG. 1. It will be appreciated in light of the present disclosure that the illustrated process flow is only one example methodology for arriving at the embodiments disclosed herein.

In FIG. 2A, the process flow begins by receiving a glass substrate 104. In wafer- or panel-level process flows, the glass substrate 104 may be a glass wafer or panel.

In FIG. 2B, one or more through-glass vias (TGVs) 106 are formed through the glass substrate 104.

In FIG. 2C, a cavity 107 is formed in the glass substrate 104. In the illustrated embodiment, the cavity 107 is a bottomless cavity extending through the entire thickness of the glass substrate 104.

In FIG. 2D, the glass substrate 104 is placed on and/or attached to a carrier substrate 122 (e.g., before embedding the bridge 110 in the cavity 107 of the glass substrate 104).

In FIG. 2E, a multi-die interconnect bridge 110 is placed face down in the cavity 107 of the glass substrate 104.

In FIG. 2F, the bridge 110 is attached and embedded face down in the cavity 107 of the glass substrate 104 using an adhesive material 109, such as a mold, epoxy, and/or dielectric material. Grinding may be performed on the backside of the bridge 110 to thin the bridge 110 until it has substantially the same thickness as the glass substrate 104 (e.g., such that the embedded bridge 110 is flush with the glass substrate 104).

In FIG. 2G, the carrier substrate 122 is removed from the glass substrate 104 (e.g., after embedding the bridge 110 in the cavity 107 of the glass substrate 104), and the glass substrate 104 is flipped over such that the bridge 110 is face up within the glass substrate 104. Further, one or more optical waveguides 108 are formed on the top surface of the glass substrate 104 (e.g., for transmission of optical signals). The completed optical/electrical interposer 102 is shown in FIG. 2G.

In FIG. 2H, various optical and electrical components are attached to the interposer 102, including an electronic integrated circuit (EIC) 112, a photonic integrated circuit (PIC) 114, and a fiber array unit (FAU) 116. For example, the EIC 112 is hybrid bonded on top of the interposer 102 such that the conductive contacts 113 on the EIC 112 are electrically coupled to TGVs 106 in the glass substrate 104 and conductive contacts 111 on the bridge 110. Similarly, the PIC 114 is hybrid bonded on top of the interposer 102 such that the conductive contacts 115 on the PIC 114 are electrically coupled to TGVs 106 in the glass substrate 104 and conductive contacts 111 on the bridge 110, and such that the PIC 114 is optically coupled to the optical waveguides 108 on the glass substrate 104. Further, the FAU 116 is attached to the interposer 102 such that the optical fibers in the FAU 116 are optically coupled to the optical waveguides 108 on the glass substrate 104.

In this manner, the EIC 112 and the PIC 114 are electrically coupled to each other through the traces 117 and vias 118 in the bridge 110. Moreover, the EIC 112 and the PIC 114 may be electrically coupled to other components through the TGVs 106 in the glass substrate 104 and/or through the TSVs 119 in the bridge 110. Further, the PIC 114 and the FAU 116 are optically coupled to each other through the optical waveguides 108 in the glass substrate 104. The completed optical interface 100 is shown in FIG. 2H.

At this point, any remaining processing may be performed, such as dielectric filling and planarization, attaching additional IC dies, packages, or other components, interconnect bump formation, singulation, and/or any other processing required to complete the finished product (e.g., a semiconductor device, microelectronic assembly, IC package, system, etc.). In some embodiments, for example, the remaining empty areas may be filled with a dielectric material. In wafer- and panel-level process flows, the wafer or panel may be diced to singulate the completed optical interfaces 100 on the wafer or panel. Further, in some embodiments, each optical interface 100 may be packaged with other components. For example, an optical interface 100 may be attached and/or electrically coupled to a package substrate and/or a circuit board along with other components, incorporated into an electronic device or system (e.g., electronic device/system 1000), etc.

FIGS. 3A-D illustrate cross-section views of various example embodiments of integrated circuit (IC) packages 300a-d with an optical/electrical glass interposer.

In FIG. 3A, optical package 300a includes an XPU 318, an EIC 312, a PIC 314, and an FAU 316 attached to an optical/electrical glass interposer 302, which in turn is attached to a package substrate 301. The interposer 302 includes multiple through-glass vias (TGVs) 306 and embedded interconnect bridges 310 (e.g., which may include through-bridge vias along with other conductive traces/vias (not shown)). In the illustrated embodiment, the XPU 318, the EIC 312, and the PIC 314 are hybrid bonded to the interposer 302, thus forming electrical connections to the TGVs 306 and the embedded bridges 310 in the interposer 302.

In particular, the XPU 318, the EIC 312, and the PIC 314 are electrically coupled to the TGVs 306 in the interposer 302, which in turn are electrically coupled to the package substrate 301. The XPU 318 and the EIC 312 are electrically coupled to one of the embedded bridges 310, which may electrically couple the XPU 318 and the EIC 312 to each other and/or to the package substrate 301. The EIC 312 and the PIC 314 are electrically coupled to the other embedded bridge 310, which may electrically couple the EIC 312 and the PIC 314 to each other and/or to the package substrate 301. Further, the PIC 314 and the FAU 316 are optically coupled to the optical waveguide(s) 308 in the interposer 302, which optically couples the PIC 314 and the FAU 316 to each other. In this manner, the XPU 318 can use the EIC 312 and the PIC 314 to communicate optically via the FAU 316.

The interposer 302 is electrically coupled to the package substrate 301 via conductive bumps 305, thus forming electrical connections between the TGVs 306/bridges 310 in the interposer 302 and the package substrate 301. Further, the package substrate 301 includes conductive bumps 303 to interconnect with other components (not shown), such as a printed circuit board (e.g., motherboard) and/or another integrated circuit package. The package substrate 301 may also include electrical routing (not shown) (e.g., conductive traces, vias, embedded interconnect bridges) to provide power and input/output (I/O) to the respective components in optical package 300a (e.g., XPU 318, EIC 312, PIC 314).

In FIG. 3B, optical package 300b is similar to optical package 300a of FIG. 3A, except the XPU 318 is hybrid bonded on top of the EIC 312 instead of the interposer 302, thus electrically coupling the XPU 318 directly to the EIC 312. As a result, the bridge 310 connecting the XPU 318 and the EIC 312 is no longer needed and is omitted.

In FIG. 3C, optical package 300c is similar to optical package 300a of FIG. 3A, except the XPU 318 is embedded in the interposer 302 (e.g., similar to the embedded bridge 310), and thus the XPU 318 is electrically coupled directly to the package substrate 301 via the conductive bumps 305 on the interposer 302. In this embodiment, the XPU 318 may be electrically coupled to other components, including the EIC 312, through conductive routing (not shown) (e.g., traces, vias) in the package substrate 301 and/or the interposer 302. As a result, the bridge 310 connecting the XPU 318 and the EIC 312 is no longer needed and is omitted.

In FIG. 3D, optical package 300d is similar to optical package 300a of FIG. 3A, except the XPU 318 is attached and electrically coupled directly to the package substrate 301 via conductive bumps 307 (e.g., adjacent to the interposer 302). In this embodiment, the XPU 318 may be electrically coupled to other components, including the EIC 312, through conductive routing (not shown) (e.g., traces, vias) in the package substrate 301. As a result, the bridge 310 connecting the XPU 318 and the EIC 312 is no longer needed and is omitted.

It should be appreciated that optical packages 300a-d are merely presented as examples. In other embodiments, certain components may be omitted, added, rearranged, modified, or combined. For simplicity, only some instances of the elements shown in optical packages 300a-d are labeled with reference numerals, and some components may be omitted. Further, some components of optical packages 300a-d may be similar to those of optical interface 100 of FIG. 1, and any of the variations described above with respect to optical interface 100 also apply to optical packages 300a-d.

The XPU 318 may include any type or combination of integrated circuitry that may use the EIC 312 and/or the PIC 314 for optical communication. For example, the XPU 318 may include any type or combination of processing units or other computing components, including, but not limited to, microcontrollers, microprocessors, processor cores, central processing units (CPUs), graphics processing units (GPUs), vision processing units (VPUs), tensor processing units (TPUs), application-specific integrated circuits (ASICs), field-programmable gate arrays (FPGAs), input/output (I/O) controllers and devices, switches, network interface controllers (NICs), persistent storage devices, and memory.

In some embodiments, optical package 300a-d may be part of an electronic device or system, such as a mobile device, a wearable device, a computer, a server, a video playback device, a video game console, a display device, a camera, or an appliance. For example, optical package 300a-d and various other electronic components may be electrically coupled to a circuit board within the electronic device.

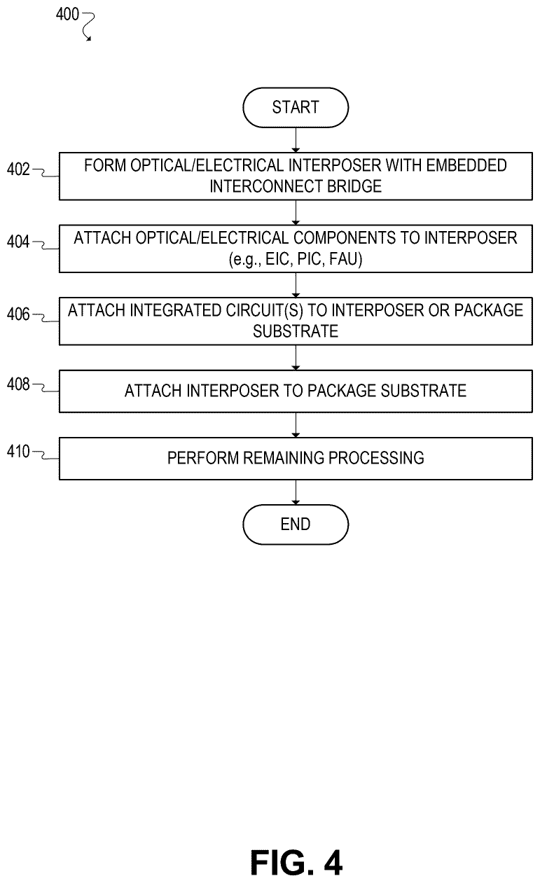

FIG. 4 illustrates a process flow 400 for forming an integrated circuit (IC) package with an optical/electrical glass interposer in accordance with certain embodiments. In some embodiments, for example, the illustrated packaging process may be used to form any of the IC packages 300a-d of FIGS. 3A-D. However, it will be appreciated in light of this disclosure that the illustrated packaging process is only one example methodology for arriving at the example IC packages and optical/electrical interposers shown and described throughout this disclosure.

The process flow begins at block 402 by forming an optical/electrical interposer with one or more embedded multi-die interconnect bridges. In some embodiments, the interposer may include a glass substrate and one or more bridge dies embedded in the glass substrate.

The glass substrate may include one or more optical waveguides to optically couple multiple optical components to each other (e.g., PIC and FAU). In some embodiments, the optical waveguides may be formed on a surface or face of the glass substrate. The glass substrate may also include one or more conductive contacts and/or through-glass vias (TGVs) to electrically couple one or more IC dies (e.g., PIC, EIC, XPU) to a package substrate.

Moreover, each bridge die may include an interconnect to electrically couple multiple IC dies (e.g., PIC, EIC, XPU) to each other and/or to the package substrate. For example, a bridge die may include a silicon substrate patterned with conductive contacts, conductive traces, and/or vias, which collectively form an interconnect to electrically couple the IC dies to each other and/or to the package substrate. Further, in some embodiments, the vias may include through-silicon vias in the silicon substrate to electrically couple one or more of the IC dies (e.g., PIC, EIC, XPU) directly to the package substrate.

In some embodiments, the optical/electrical glass interposer may be formed using the process flow shown and described in connection with FIGS. 2A-G.

The process flow then proceeds to block 404 to attach various optical and/or electrical components to the interposer, such as an electronic integrated circuit (EIC), a photonic integrated circuit (PIC), and/or a fiber array unit (FAU).

In some embodiments, for example, the PIC and the EIC may be coupled to the glass substrate and/or the embedded bridge via a hybrid dielectric and metal bond, a solder bond, or any other suitable bonding mechanism capable of forming the requisite optical and electrical connections. For example, the PIC may be optically coupled to the optical waveguides on the glass substrate and electrically coupled to conductive contacts on the bridge die and/or the glass substrate. Moreover, the EIC may be electrically coupled to conductive contacts on the bridge die and/or the glass substrate. In this manner, the PIC and the EIC may be electrically coupled to each other and/or to the package substrate via the interconnect (e.g., contacts, traces, vias/TSVs) in the bridge die and/or the TGVs in the glass substrate.

The FAU may include one or more optical fibers (or other types of optical waveguides), which may be optically coupled to the optical waveguides in the glass interposer using any suitable optical coupling mechanisms (e.g., an optical coupler, v-grooves, adhesives). In this manner, the FAU and the PIC are optically coupled to each other via the optical waveguides in the glass interposer.

The resulting assembly (e.g., the interposer, EIC, PIC, and/or FAU) may be referred to as an optical interface.

The process flow then proceeds to block 406 to attach and electrically couple one or more integrated circuits (ICs) to the interposer or the package substrate (e.g., using hybrid bonding, solder bonding, etc.). In some embodiments, for example, an IC may be attached to the surface/face of the interposer, attached to another component on the interposer (e.g., on top of the EIC), or embedded within a cavity in the interposer. Alternatively, the IC may be attached directly to the package substrate. Moreover, the IC may be electrically coupled to the package substrate (e.g., directly or indirectly through the interposer) for power and signaling (e.g., I/O), and the IC may be electrically coupled to the optical interface (e.g., the EIC/PIC) to enable the IC to communicate optically via the optical interface.

Further, the IC may be packaged or unpackaged (e.g., an IC die, an IC package with one or more IC dies). The IC may include any type or combination of circuitry, including, without limitation, processing circuitry, memory circuitry, storage circuitry, and/or communication circuitry. In some embodiments, for example, the IC may include, without limitation, a microcontroller, a microprocessor, an XPU (e.g., central processing unit (CPU), graphics processing unit (GPU), vision processing unit (VPU), tensor processing unit (TPU)), an application-specific integrated circuit (ASIC), a field-programmable gate array (FPGA), a switch, a network interface controller (NIC), a memory device (e.g., memory, memory controller), and/or a persistent storage device (e.g., hard disk drive (HDD), solid state drive (SSD)), among other examples.

The process flow then proceeds to block 408 to attach and electrically couple the interposer to the package substrate. In some embodiments, for example, the interposer may be attached and electrically coupled to the surface of the package substrate via conductive contacts.

In some embodiments, the package substrate may include a glass substrate or an organic substrate (e.g., made of organic compounds or materials) patterned with one or more conductive contacts (e.g., pads, bumps/balls), conductive traces/vias, and/or embedded interconnect bridges that collectively form an electrical interconnect. For example, conductive contacts may be patterned on the top surface of the package substrate to form a first level interconnect (FLI) for components attached to the package substrate (e.g., interposer, EIC, PIC, XPU), and conductive contacts may be patterned on the bottom surface of the package substrate to form a second level interconnect (SLI) to a next-level component, such as a printed circuit board and/or another integrated circuit package. The conductive traces, vias, and/or embedded interconnect bridges may form electrical connections to, from, and/or between the components electrically coupled to the conductive contacts on the package substrate (e.g., interposer, EIC, PIC, XPU) to provide power and signal routing.

The process flow then proceeds to block 410 to perform any remaining processing, such as dielectric filling and planarization, attaching additional IC dies, packages, or other components, interconnect bump formation, singulation, and/or any other processing required to complete the finished product (e.g., a semiconductor device, microelectronic assembly, IC package, system, etc.). In some embodiments, for example, the remaining empty areas in the IC package may be filled with a dielectric material. In wafer- and panel-level process flows, the wafer or panel may be diced to singulate the completed IC packages on the wafer or panel. Further, in some embodiments, each IC package may be attached and/or electrically coupled to a circuit board or another IC package or substrate, and/or may be incorporated into an electronic device or system (e.g., electronic device/system 1000).

At this point, the process flow may be complete. In some embodiments, however, the process flow may restart and/or certain blocks may be repeated. For example, in some embodiments, the process flow may restart at block 402 to continue forming IC packages with optical/electrical interposers.

FIGS. 5A-B illustrate examples of hybrid dielectric/metal bonds that may be used in any of the embodiments described herein. In particular, a hybrid bond 500a using inorganic dielectrics is shown in FIG. 5A, and a hybrid bond 500b using organic dielectrics is shown in FIG. 5B. In some embodiments, hybrid bonds 500a-b may be used to bond optical and/or electrical components (e.g., EIC 112, 312, PIC 114, 314, XPU 318) to an optical/electrical interposer (e.g., interposer 102, 302) and/or a package substrate (e.g., package substrate 301), as described further throughout this disclosure.

In FIG. 5A, an integrated circuit (IC) die 510 is hybrid bonded to a glass substrate 520 using inorganic dielectrics (e.g., SiOₓ). In particular, the bottom surface of the die 510 includes an inorganic dielectric layer 511 (e.g., SiOₓ) with a conductive contact 514 (e.g., copper (Cu) pad), and the glass substrate 520 (e.g., SiOₓ) includes a through-glass via (TGV) 526 (e.g., Cu via) extending between its top and bottom surfaces. Moreover, the die 510 is hybrid bonded on top of the glass substrate 520, such that the dielectric layer 511 on the die 510 is bonded to the dielectric surface of the glass substrate 520, and the conductive contact 514 on the die 510 is bonded and electrically coupled to the TGV 526 in the glass substrate 520. In this manner, a hybrid metal (e.g., Cu—Cu) and dielectric (e.g., SiOₓ—SiOₓ) bond is formed between the die 510 and the substrate 520. In various embodiments, any suitable conductive and inorganic dielectric materials may be used to form the hybrid bond 500a, including, without limitation, copper and glass/SiOₓ.

In FIG. 5B, an IC die 510 is hybrid bonded to a glass substrate 520 using organic dielectrics (e.g., polyimide). In particular, the bottom surface of the die 510 includes an organic dielectric layer 512 (e.g., polyimide) with a conductive contact 514 (e.g., Cu pad), and the top surface of the glass substrate 520 includes an organic dielectric layer 522 (e.g., polyimide) with a conductive contact 524 (e.g., Cu pad), which is electrically coupled to the TGV 526 in the glass substrate 520. Moreover, the die 510 is hybrid bonded on top of the glass substrate 520, such that the dielectric layer 512 on the die 510 is bonded to the dielectric layer 522 on the glass substrate 520, and the conductive contact 514 on the die 510 is bonded and electrically coupled to the conductive contact 524 on the glass substrate 520. In this manner, a hybrid metal (e.g., Cu—Cu) and dielectric (e.g., PI-PI) bond is formed between the die 510 and the substrate 520. In various embodiments, any suitable conductive and organic dielectric materials may be used to form the hybrid bond 500b, including, without limitation, copper and polyimide.

### Example Integrated Circuit Embodiments

FIG. 6 is a cross-sectional view of an example bridge 630 (e.g., bridges 110, 310) embedded within a substrate 600 (e.g., a package substrate). Multiple integrated circuit (IC) dies 610, 620 are attached and electrically coupled to the substrate 600 via a hybrid dielectric and metal bond. For example, the substrate 600 and the dies 610, 620 each have a surface with a dielectric layer 603, 613, 623 and conductive contacts 602, 612, 622. Moreover, the dies 610, 620 are hybrid bonded to the substrate 600 to form hybrid dielectric-to-dielectric and metal-to-metal bonds between each die 610, 620 and the substrate 600, such that the dielectric layer 613, 623 on each die 610, 620 is bonded to the dielectric layer 603 on the substrate 600 and the conductive contacts 612, 622 on each die 610, 620 are bonded to conductive contacts 602 on the substrate 600. The substrate 600 includes dielectric layers 603, 605 along with conductive contacts 602, vias 604, traces 606, and an embedded bridge 630. The conductive contacts 602 are on the top and bottom surfaces of the substrate 600. The vias 604 and conductive traces 606 form conductive pathways between the conductive contacts 602 on the substrate 600 and/or from the conductive contacts 602 on the substrate 600 to conductive contacts 632 on the bridge 630. The bridge 630 includes a substrate (e.g., made of silicon) patterned with an interconnect to electrically couple the dies 610, 620 to each other and/or other components. For example, the bridge 630 includes conductive contacts 632 on the top and bottom surfaces, along with vias 634 and conductive traces 636 to form conductive pathways between the conductive contacts 632. In particular, some conductive contacts 632 are electrically coupled to each other by vias 634 and traces 636, while others are electrically coupled to each other by through-bridge vias 634 extending through the bridge 630 between the top and bottom surfaces (e.g., through-silicon vias in a silicon substrate). Together, the conductive contacts 602, 632, vias 604, 634, and conductive traces 606, 636 of the substrate 600 and the bridge 630 form conductive pathways to electrically couple the dies 610, 620 to each other and/or to other components (e.g., on or off package, such as a power supply).

Although the embedded bridge 630 is shown as being fully embedded within the substrate 600, in other embodiments the bridge 630 may be embedded such that the top and/or bottom surfaces of the bridge 630 are flush with the top and/or bottom surfaces of the substrate 600. In such embodiments, the IC dies 610, 620 may be hybrid bonded to both the substrate 600 and the bridge 630, such that the conductive contacts 612, 622 on the dies 610, 620 are bonded and electrically coupled to conductive contacts 602, 632 on both the substrate 600 and the bridge 630. Further, while the dies 610, 620 are hybrid bonded to the substrate 600 in the illustrated embodiment, in other embodiments the dies 610, 620 may be solder bonded to the substrate 600 using conductive balls or bumps, or any other suitable approach may be used to attach and/or electrically couple the dies 610, 620 to the substrate 600. The substrate 600 may be made of any suitable material(s), including, without limitation, organic materials or glass, and may be a cored or coreless substrate. The bridge substrate 630 may be made of any suitable material(s), including, without limitation, silicon. Further, the substrate 600 may be attached and/or electrically coupled to other component(s) such as a printed circuit board (PCB) (e.g., via the conductive contacts 608 on the bottom surface of substrate 600). For simplicity, only some instances of the elements shown in the illustrated embodiment are labeled with reference numerals.

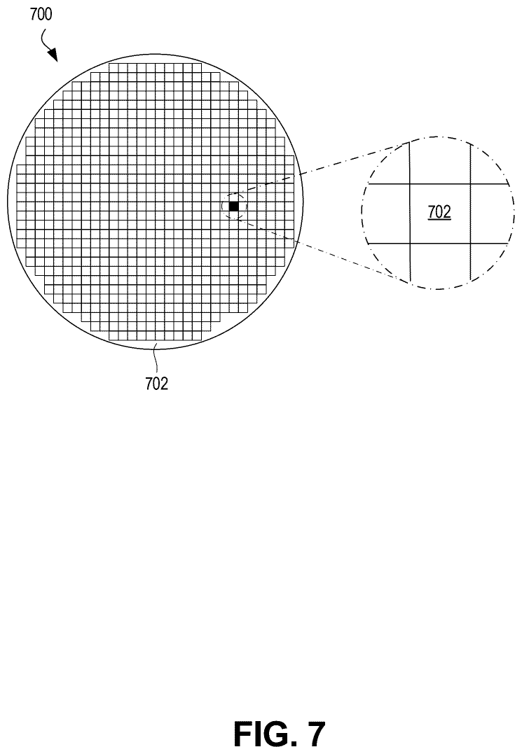

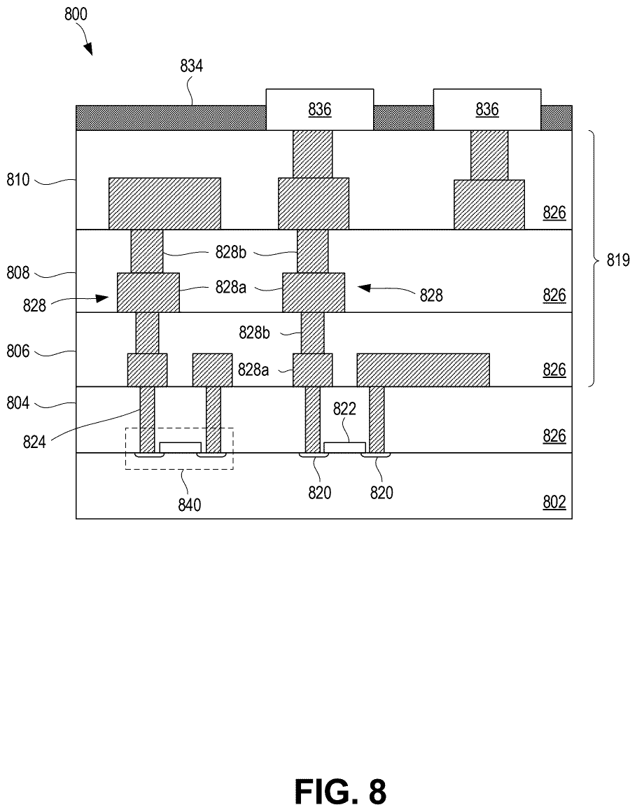

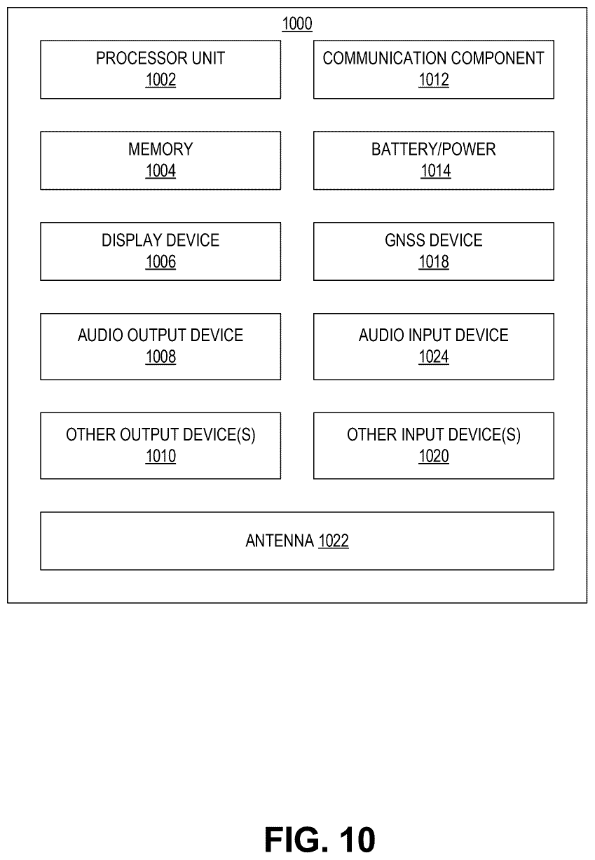

FIG. 7 is a top view of a wafer 700 and dies 702 that may be included in any of the embodiments disclosed herein. The wafer 700 may be composed of semiconductor material and may include one or more dies 702 having integrated circuit structures formed on a surface of the wafer 700. The individual dies 702 may be a repeating unit of an integrated circuit product that includes any suitable integrated circuit. After the fabrication of the semiconductor product is complete, the wafer 700 may undergo a singulation process in which the dies 702 are separated from one another to provide discrete “chips” of the integrated circuit product. The die 702 may be any of the dies disclosed herein. The die 702 may include one or more transistors (e.g., some of the transistors 840 of FIG. 8, discussed below), supporting circuitry to route electrical signals to the transistors, passive components (e.g., signal traces, resistors, capacitors, or inductors), and/or any other integrated circuit components. In some embodiments, the wafer 700 or the die 702 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 702. For example, a memory array formed by multiple memory devices may be formed on a same die 702 as a processor unit (e.g., the processor unit 1002 of FIG. 10) or other logic that is configured to store information in the memory devices or execute instructions stored in the memory array. Various ones of the microelectronic assemblies disclosed herein may be manufactured using a die-to-wafer assembly technique in which some dies are attached to a wafer 700 that include others of the dies, and the wafer 700 is subsequently singulated.

FIG. 8 is a cross-sectional side view of an integrated circuit device 800 that may be included in any of the embodiments disclosed herein (e.g., in any of the dies, such as EICs 112, 312, PICs 114, 314, XPUs 318). One or more of the integrated circuit devices 800 may be included in one or more dies 702 (FIG. 7). The integrated circuit device 800 may be formed on a die substrate 802 (e.g., the wafer 700 of FIG. 7) and may be included in a die (e.g., the die 702 of FIG. 7). The die substrate 802 may be a semiconductor substrate composed of semiconductor material systems including, for example, n-type or p-type materials systems (or a combination of both). The die substrate 802 may include, for example, a crystalline substrate formed using a bulk silicon or a silicon-on-insulator (SOI) substructure. In some embodiments, the die substrate 802 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 802. Although a few examples of materials from which the die substrate 802 may be formed are described here, any material that may serve as a foundation for an integrated circuit device 800 may be used. The die substrate 802 may be part of a singulated die (e.g., the dies 702 of FIG. 7) or a wafer (e.g., the wafer 700 of FIG. 7).

The integrated circuit device 800 may include one or more device layers 804 disposed on the die substrate 802. The device layer 804 may include features of one or more transistors 840 (e.g., metal oxide semiconductor field-effect transistors (MOSFETs)) formed on the die substrate 802. The transistors 840 may include, for example, one or more source and/or drain (S/D) regions 820, a gate 822 to control current flow between the S/D regions 820, and one or more S/D contacts 824 to route electrical signals to/from the S/D regions 820. The transistors 840 may include additional features not depicted for the sake of clarity, such as device isolation regions, gate contacts, and the like. The transistors 840 are not limited to the type and configuration depicted in FIG. 8 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

A transistor 840 may include a gate 822 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 840 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 840 along the source-channel-drain direction, the gate electrode may consist of a U-shaped structure that includes a bottom portion substantially parallel to the surface of the die substrate 802 and two sidewall portions that are substantially perpendicular to the top surface of the die substrate 802. In other embodiments, at least one of the metal layers that form the gate electrode may simply be a planar layer that is substantially parallel to the top surface of the die substrate 802 and does not include sidewall portions substantially perpendicular to the top surface of the die substrate 802. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 820 may be formed within the die substrate 802 adjacent to the gate 822 of individual transistors 840. The S/D regions 820 may be formed using an implantation/diffusion process or an etching/deposition process, for example. In the former process, dopants such as boron, aluminum, antimony, phosphorous, or arsenic may be ion-implanted into the die substrate 802 to form the S/D regions 820. An annealing process that activates the dopants and causes them to diffuse farther into the die substrate 802 may follow the ion-implantation process. In the latter process, the die substrate 802 may first be etched to form recesses at the locations of the S/D regions 820. An epitaxial deposition process may then be carried out to fill the recesses with material that is used to fabricate the S/D regions 820. In some implementations, the S/D regions 820 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 820 may be formed using one or more alternate semiconductor materials such as germanium or a group III-V material or alloy. In further embodiments, one or more layers of metal and/or metal alloys may be used to form the S/D regions 820.

Electrical signals, such as power and/or input/output (I/O) signals, may be routed to and/or from the devices (e.g., transistors 840) of the device layer 804 through one or more interconnect layers disposed on the device layer 804 (illustrated in FIG. 8 as interconnect layers 806-810). For example, electrically conductive features of the device layer 804 (e.g., the gate 822 and the S/D contacts 824) may be electrically coupled with the interconnect structures 828 of the interconnect layers 806-810. The one or more interconnect layers 806-810 may form a metallization stack (also referred to as an “ILD stack”) 819 of the integrated circuit device 800.

The interconnect structures 828 may be arranged within the interconnect layers 806-810 to route electrical signals according to a wide variety of designs; in particular, the arrangement is not limited to the particular configuration of interconnect structures 828 depicted in FIG. 8. Although a particular number of interconnect layers 806-810 is depicted in FIG. 8, embodiments of the present disclosure include integrated circuit devices having more or fewer interconnect layers than depicted.

In some embodiments, the interconnect structures 828 may include lines 828a and/or vias 828b filled with an electrically conductive material such as a metal. The lines 828a may be arranged to route electrical signals in a direction of a plane that is substantially parallel with a surface of the die substrate 802 upon which the device layer 804 is formed. For example, the lines 828a may route electrical signals in a direction in and out of the page and/or in a direction across the page from the perspective of FIG. 8. The vias 828b may be arranged to route electrical signals in a direction of a plane that is substantially perpendicular to the surface of the die substrate 802 upon which the device layer 804 is formed. In some embodiments, the vias 828b may electrically couple lines 828a of different interconnect layers 806-810 together.

The interconnect layers 806-810 may include a dielectric material 826 disposed between the interconnect structures 828, as shown in FIG. 8. In some embodiments, dielectric material 826 disposed between the interconnect structures 828 in different ones of the interconnect layers 806-810 may have different compositions; in other embodiments, the composition of the dielectric material 826 between different interconnect layers 806-810 may be the same. The device layer 804 may include a dielectric material 826 disposed between the transistors 840 and a bottom layer of the metallization stack as well. The dielectric material 826 included in the device layer 804 may have a different composition than the dielectric material 826 included in the interconnect layers 806-810; in other embodiments, the composition of the dielectric material 826 in the device layer 804 may be the same as a dielectric material 826 included in any one of the interconnect layers 806-810.

A first interconnect layer 806 (referred to as Metal 1 or “M1”) may be formed directly on the device layer 804. In some embodiments, the first interconnect layer 806 may include lines 828a and/or vias 828b, as shown. The lines 828a of the first interconnect layer 806 may be coupled with contacts (e.g., the S/D contacts 824) of the device layer 804. The vias 828b of the first interconnect layer 806 may be coupled with the lines 828a of a second interconnect layer 808.

The second interconnect layer 808 (referred to as Metal 2 or “M2”) may be formed directly on the first interconnect layer 806. In some embodiments, the second interconnect layer 808 may include via 828b to couple the lines 828 of the second interconnect layer 808 with the lines 828a of a third interconnect layer 810. Although the lines 828a and the vias 828b are structurally delineated with a line within individual interconnect layers for the sake of clarity, the lines 828a and the vias 828b may be structurally and/or materially contiguous (e.g., simultaneously filled during a dual-damascene process) in some embodiments.

The third interconnect layer 810 (referred to as Metal 3 or “M3”) (and additional interconnect layers, as desired) may be formed in succession on the second interconnect layer 808 according to similar techniques and configurations described in connection with the second interconnect layer 808 or the first interconnect layer 806. In some embodiments, the interconnect layers that are “higher up” in the metallization stack 819 in the integrated circuit device 800 (i.e., farther away from the device layer 804) may be thicker that the interconnect layers that are lower in the metallization stack 819, with lines 828a and vias 828b in the higher interconnect layers being thicker than those in the lower interconnect layers.

The integrated circuit device 800 may include a solder resist material 834 (e.g., polyimide or similar material) and one or more conductive contacts 836 formed on the interconnect layers 806-810. In FIG. 8, the conductive contacts 836 are illustrated as taking the form of bond pads. The conductive contacts 836 may be electrically coupled with the interconnect structures 828 and configured to route the electrical signals of the transistor(s) 840 to external devices. For example, solder bonds may be formed on the one or more conductive contacts 836 to mechanically and/or electrically couple an integrated circuit die including the integrated circuit device 800 with another component (e.g., a printed circuit board). The integrated circuit device 800 may include additional or alternate structures to route the electrical signals from the interconnect layers 806-810; for example, the conductive contacts 836 may include other analogous features (e.g., posts) that route the electrical signals to external components. The conductive contacts 836 may serve as any of the conductive contacts described throughout this disclosure.

In some embodiments in which the integrated circuit device 800 is a double-sided die, the integrated circuit device 800 may include another metallization stack (not shown) on the opposite side of the device layer(s) 804. This metallization stack may include multiple interconnect layers as discussed above with reference to the interconnect layers 806-810, to provide conductive pathways (e.g., including conductive lines and vias) between the device layer(s) 804 and additional conductive contacts (not shown) on the opposite side of the integrated circuit device 800 from the conductive contacts 836. These additional conductive contacts may serve as any of the conductive contacts described throughout this disclosure.

In other embodiments in which the integrated circuit device 800 is a double-sided die, the integrated circuit device 800 may include one or more through silicon vias (TSVs) through the die substrate 802; these TSVs may make contact with the device layer(s) 804, and may provide conductive pathways between the device layer(s) 804 and additional conductive contacts (not shown) on the opposite side of the integrated circuit device 800 from the conductive contacts 836. These additional conductive contacts may serve as any of the conductive contacts described throughout this disclosure. In some embodiments, TSVs extending through the substrate can be used for routing power and ground signals from conductive contacts on the opposite side of the integrated circuit device 800 from the conductive contacts 836 to the transistors 840 and any other components integrated into the die 800, and the metallization stack 819 can be used to route I/O signals from the conductive contacts 836 to transistors 840 and any other components integrated into the die 800.

Multiple integrated circuit devices 800 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

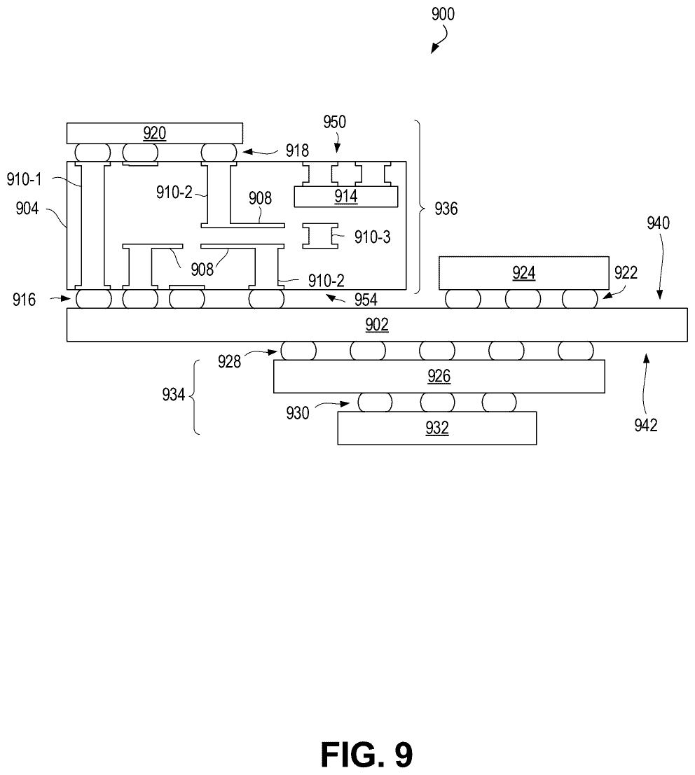

FIG. 9 is a cross-sectional side view of an integrated circuit device assembly 900 that may include any of the embodiments disclosed herein (e.g., one or more optical packages 300a-d, optical interfaces 100, optical/electrical interposers 102, 302, EICs 112, 312, PICs 114, 314, FAUs 116, 316, XPUs 318). In some embodiments, the integrated circuit device assembly 900 may be a microelectronic assembly. The integrated circuit device assembly 900 includes a number of components disposed on a circuit board 902 (which may be a motherboard, system board, mainboard, etc.). The integrated circuit device assembly 900 includes components disposed on a first face 940 of the circuit board 902 and an opposing second face 942 of the circuit board 902; generally, components may be disposed on one or both faces 940 and 942. Any of the integrated circuit components discussed below with reference to the integrated circuit device assembly 900 may take the form of any suitable ones of the embodiments of the microelectronic assemblies disclosed herein.

In some embodiments, the circuit board 902 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 902. In other embodiments, the circuit board 902 may be a non-PCB substrate. The integrated circuit device assembly 900 illustrated in FIG. 9 includes a package-on-interposer structure 936 coupled to the first face 940 of the circuit board 902 by coupling components 916. The coupling components 916 may electrically and mechanically couple the package-on-interposer structure 936 to the circuit board 902, and may include solder balls (as shown in FIG. 9), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 916 may serve as the coupling components illustrated or described for any of the substrate assembly or substrate assembly components described herein, as appropriate.

The package-on-interposer structure 936 may include an integrated circuit component 920 coupled to an interposer 904 by coupling components 918. The coupling components 918 may take any suitable form for the application, such as the forms discussed above with reference to the coupling components 916. Although a single integrated circuit component 920 is shown in FIG. 9, multiple integrated circuit components may be coupled to the interposer 904; indeed, additional interposers may be coupled to the interposer 904. The interposer 904 may provide an intervening substrate used to bridge the circuit board 902 and the integrated circuit component 920.

The integrated circuit component 920 may be a packaged or unpacked integrated circuit product that includes one or more integrated circuit dies (e.g., the die 702 of FIG. 7, the integrated circuit device 800 of FIG. 8) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 920, a single monolithic integrated circuit die comprises solder bumps attached to contacts on the die. The solder bumps allow the die to be directly attached to the interposer 904. The integrated circuit component 920 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 920 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 920 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 920 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 904 may spread connections to a wider pitch or reroute a connection to a different connection. For example, the interposer 904 may couple the integrated circuit component 920 to a set of ball grid array (BGA) conductive contacts of the coupling components 916 for coupling to the circuit board 902. In the embodiment illustrated in FIG. 9, the integrated circuit component 920 and the circuit board 902 are attached to opposing sides of the interposer 904; in other embodiments, the integrated circuit component 920 and the circuit board 902 may be attached to a same side of the interposer 904. In some embodiments, three or more components may be interconnected by way of the interposer 904.

In some embodiments, the interposer 904 may be formed as a PCB, including multiple metal layers separated from one another by layers of dielectric material and interconnected by electrically conductive vias. In some embodiments, the interposer 904 may be formed of an epoxy resin, a fiberglass-reinforced epoxy resin, an epoxy resin with inorganic fillers, a ceramic material, or a polymer material such as polyimide. In some embodiments, the interposer 904 may be formed of alternate rigid or flexible materials that may include the same materials described above for use in a semiconductor substrate, such as silicon, germanium, and other group III-V and group IV materials. The interposer 904 may include metal interconnects 908 and vias 910, including but not limited to through hole vias 910-1 (that extend from a first face 950 of the interposer 904 to a second face 954 of the interposer 904), blind vias 910-2 (that extend from the first or second faces 950 or 954 of the interposer 904 to an internal metal layer), and buried vias 910-3 (that connect internal metal layers).

In some embodiments, the interposer 904 can comprise a silicon interposer. Through silicon vias (TSV) extending through the silicon interposer can connect connections on a first face of a silicon interposer to an opposing second face of the silicon interposer. In some embodiments, an interposer 904 comprising a silicon interposer can further comprise one or more routing layers to route connections on a first face of the interposer 904 to an opposing second face of the interposer 904.

The interposer 904 may further include embedded devices 914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 904. The package-on-interposer structure 936 may take the form of any of the package-on-interposer structures known in the art. In embodiments where the interposer is a non-printed circuit board

The integrated circuit device assembly 900 may include an integrated circuit component 924 coupled to the first face 940 of the circuit board 902 by coupling components 922. The coupling components 922 may take the form of any of the embodiments discussed above with reference to the coupling components 916, and the integrated circuit component 924 may take the form of any of the embodiments discussed above with reference to the integrated circuit component 920.

The integrated circuit device assembly 900 illustrated in FIG. 9 includes a package-on-package structure 934 coupled to the second face 942 of the circuit board 902 by coupling components 928. The package-on-package structure 934 may include an integrated circuit component 926 and an integrated circuit component 932 coupled together by coupling components 930 such that the integrated circuit component 926 is disposed between the circuit board 902 and the integrated circuit component 932. The coupling components 928 and 930 may take the form of any of the embodiments of the coupling components 916 discussed above, and the integrated circuit components 926 and 932 may take the form of any of the embodiments of the integrated circuit component 920 discussed above. The package-on-package structure 934 may be configured in accordance with any of the package-on-package structures known in the art.

FIG. 10 is a block diagram of an example electronic device 1000 that may include one or more of the embodiments disclosed herein. For example, any suitable ones of the components of the electronic device 1000 may include one or more of the optical components (e.g., optical packages 300a-d, optical interfaces 100, optical/electrical interposers 102, 302, EICs 112, 312, PICs 114, 314, FAUs 116, 316, XPUs 318), integrated circuit device assemblies 900, integrated circuit components 920, integrated circuit devices 800, or integrated circuit dies 702 disclosed herein. In some embodiments, for example, the electronic device 1000 and/or its respective components (e.g., processor units 1002, input/output (I/O) devices 1010, 1020, communication components 1012, memory 1004) may include an optical interface for optical communication according to any of the embodiments described herein. A number of components are illustrated in FIG. 10 as included in the electronic device 1000, but any one or more of these components may be omitted or duplicated, as suitable for the application. In some embodiments, some or all of the components included in the electronic device 1000 may be attached to one or more motherboards mainboards, or system boards. In some embodiments, one or more of these components are fabricated onto a single system-on-a-chip (SoC) die.

Additionally, in various embodiments, the electronic device 1000 may not include one or more of the components illustrated in FIG. 10, but the electronic device 1000 may include interface circuitry for coupling to the one or more components. For example, the electronic device 1000 may not include a display device 1006, but may include display device interface circuitry (e.g., a connector and driver circuitry) to which a display device 1006 may be coupled. In another set of examples, the electronic device 1000 may not include an audio input device 1024 or an audio output device 1008, but may include audio input or output device interface circuitry (e.g., connectors and supporting circuitry) to which an audio input device 1024 or audio output device 1008 may be coupled.

The electronic device 1000 may include one or more processor units 1002 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electronic device 1000 may include a memory 1004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1004 may include memory that is located on the same integrated circuit die as the processor unit 1002. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electronic device 1000 can comprise one or more processor units 1002 that are heterogeneous or asymmetric to another processor unit 1002 in the electronic device 1000. There can be a variety of differences between the processing units 1002 in a system in terms of a spectrum of metrics of merit including architectural, microarchitectural, thermal, power consumption characteristics, and the like. These differences can effectively manifest themselves as asymmetry and heterogeneity among the processor units 1002 in the electronic device 1000.

In some embodiments, the electronic device 1000 may include a communication component 1012 (e.g., one or more communication components). For example, the communication component 1012 can manage wireless communications for the transfer of data to and from the electronic device 1000. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1012 may operate in accordance with other wireless protocols in other embodiments. The electronic device 1000 may include an antenna 1022 to facilitate wireless communications and/or to receive other wireless communications (such as AM or FM radio transmissions).

In some embodiments, the communication component 1012 may manage wired communications, such as electrical, optical, or any other suitable communication protocols (e.g., IEEE 802.3 Ethernet standards). As noted above, the communication component 1012 may include multiple communication components. For instance, a first communication component 1012 may be dedicated to shorter-range wireless communications such as Wi-Fi or Bluetooth, and a second communication component 1012 may be dedicated to longer-range wireless communications such as global positioning system (GPS), EDGE, GPRS, CDMA, WiMAX, LTE, EV-DO, or others. In some embodiments, a first communication component 1012 may be dedicated to wireless communications, and a second communication component 1012 may be dedicated to wired communications.

The electronic device 1000 may include battery/power circuitry 1014. The battery/power circuitry 1014 may include one or more energy storage devices (e.g., batteries or capacitors) and/or circuitry for coupling components of the electronic device 1000 to an energy source separate from the electronic device 1000 (e.g., AC line power).

The electronic device 1000 may include a display device 1006 (or corresponding interface circuitry, as discussed above). The display device 1006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electronic device 1000 may include an audio output device 1008 (or corresponding interface circuitry, as discussed above). The audio output device 1008 may include any embedded or wired or wirelessly connected external device that generates an audible indicator, such speakers, headsets, or earbuds.

The electronic device 1000 may include an audio input device 1024 (or corresponding interface circuitry, as discussed above). The audio input device 1024 may include any embedded or wired or wirelessly connected device that generates a signal representative of a sound, such as microphones, microphone arrays, or digital instruments (e.g., instruments having a musical instrument digital interface (MIDI) output). The electronic device 1000 may include a Global Navigation Satellite System (GNSS) device 1018 (or corresponding interface circuitry, as discussed above), such as a Global Positioning System (GPS) device. The GNSS device 1018 may be in communication with a satellite-based system and may determine a geolocation of the electronic device 1000 based on information received from one or more GNSS satellites, as known in the art.

The electronic device 1000 may include other output device(s) 1010 (or corresponding interface circuitry, as discussed above). Examples of the other output device(s) 1010 may include an audio codec, a video codec, a printer, a wired or wireless transmitter for providing information to other devices, or an additional storage device.

The electronic device 1000 may include other input device(s) 1020 (or corresponding interface circuitry, as discussed above). Examples of the other input device(s) 1020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1000 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a display device (e.g., monitor, television), a set-top box, an entertainment control unit, a video game console, a video playback device, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1000 may be any other electronic device that processes data. In some embodiments, the electrical device 1000 may comprise multiple discrete physical components. Given the range of devices that the electrical device 1000 can be manifested as in various embodiments, in some embodiments, the electrical device 1000 can be referred to as a computing device or a computing system.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features. Further, it should be understood that the various embodiments shown in the figures are illustrative representations and are not necessarily drawn to scale.

Moreover, the illustrations and/or descriptions of various embodiments may be simplified or approximated for ease of understanding, and as a result, they may not necessarily reflect the level of precision nor variation that may be present in actual embodiments. For example, while some figures generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for ease of understanding and may vary by some margin of error in actual embodiments (e.g., due to fabrication processes, etc.).

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

The terms “substantially,” “close,” “approximately,” “near,” and “about,” generally refer to being within +/−10% of a target value (unless otherwise specified). Similarly, terms describing spatial relationships, such as “perpendicular,” “orthogonal,” or “coplanar,” may refer to being substantially within the described spatial relationships (e.g., within +/−10 degrees of orthogonality).

Certain terminology may also be used in the foregoing description for the purpose of reference only, and thus are not intended to be limiting. For example, terms such as “upper,” “lower,” “above,” “below,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

The terms “over”, “between”, “adjacent”, “to”, and “on” as used herein may refer to a relative position of one layer or component with respect to other layers or components. For example, one layer “over” or “on” another layer, “adjacent” to another layer, or bonded “to” another layer may be directly in contact with the other layer or may have one or more intervening layers. One layer “between” layers may be directly in contact with the layers or may have one or more intervening layers.

The meaning of “a,” “an,” and “the” include plural references. The meaning of “in” includes “in” and “on.”

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

The term “cored” generally refers to a substrate of an integrated circuit package built upon a board, card or wafer comprising a non-flexible stiff material. In some cases, a small printed circuit board may be used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

The term “coreless” generally refers to a substrate of an integrated circuit package having no core. The lack of a core allows for higher-density package architectures, as the through-vias have relatively large dimensions and pitch compared to high-density interconnects.

The term “land side”, if used herein, generally refers to the side of the substrate of the integrated circuit package closest to the plane of attachment to a printed circuit board, motherboard, or other package. This is in contrast to the term “die side”, which is the side of the substrate of the integrated circuit package to which the die or dice are attached.

The term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

The term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and carries the same meaning.

The term “solder bump” generally refers to a solder layer formed on a bond pad. The solder layer typically has a round shape, hence the term “solder bump”.

The term “substrate” generally refers to a planar platform comprising dielectric and/or metallization structures. The substrate may mechanically support and electrically couple one or more IC dies on a single platform, with encapsulation of the one or more IC dies by a moldable dielectric material. The substrate generally comprises solder bumps as bonding interconnects on both sides. One side of the substrate, generally referred to as the “die side”, may comprise solder bumps for chip or die bonding. The opposite side of the substrate, generally referred to as the “land side”, may comprise solder bumps for bonding the package to a printed circuit board.

The term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

The terms “coupled” or “connected” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal.

### EXAMPLES

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes a semiconductor device, comprising: a glass substrate comprising one or more optical waveguides; and a bridge die embedded in the glass substrate, wherein the bridge die comprises an interconnect to electrically couple a plurality of integrated circuit (IC) dies.

Example 2 includes the semiconductor device of Example 1, wherein the glass substrate further comprises one or more through-glass vias.

Example 3 includes the semiconductor device of any of Examples 1-2, wherein: the bridge die further comprises a silicon substrate; and the interconnect comprises one or more conductive traces on the silicon substrate.

Example 4 includes the semiconductor device of Example 3, wherein the interconnect further comprises one or more through-silicon vias in the silicon substrate.

Example 5 includes the semiconductor device of any of Examples 1-4, wherein the one or more optical waveguides are at least partially on a surface of the glass substrate.

Example 6 includes the semiconductor device of any of Examples 1-5, further comprising the plurality of IC dies, wherein: the plurality of IC dies include a photonic integrated circuit (PIC) and an electronic integrated circuit (EIC); the PIC and the EIC are coupled to the glass substrate; the PIC and the EIC are electrically coupled to each other via the interconnect in the bridge die; and the PIC is optically coupled to the one or more optical waveguides.

Example 7 includes the semiconductor device of Example 6, further comprising one or more optical fibers, wherein the one or more optical fibers are optically coupled to the one or more optical waveguides, and wherein the one or more optical fibers and the PIC are optically coupled via the one or more optical waveguides.

Example 8 includes the semiconductor device of any of Examples 6-7, wherein the PIC and the EIC are respectively coupled to the glass substrate via a hybrid dielectric and metal bond.

Example 9 includes the semiconductor device of any of Examples 1-8, wherein the semiconductor device is: an optical and electrical interposer; an optical interface; or an IC package comprising an optical interface.

Example 10 includes a microelectronic assembly, comprising: a package substrate; an interposer coupled to the package substrate, wherein the interposer comprises: a glass substrate comprising one or more optical waveguides; and a bridge die embedded in the glass substrate, wherein the bridge die comprises one or more conductive traces; a photonic integrated circuit (PIC) coupled to the interposer, wherein the PIC is optically coupled to the one or more optical waveguides, and wherein the PIC is electrically coupled to the bridge die; and an electronic integrated circuit (EIC) coupled to the interposer, wherein the EIC is electrically coupled to the bridge die, and wherein the EIC and the PIC are electrically coupled to each other via the one or more conductive traces in the bridge die.

Example 11 includes the microelectronic assembly of Example 10, wherein the glass substrate further comprises one or more through-glass vias, wherein the one or more through-glass vias electrically couple at least one of the PIC or the EIC to the package substrate.

Example 12 includes the microelectronic assembly of any of Examples 10-11, wherein the bridge die further comprises: a silicon substrate, wherein the one or more conductive traces are on the silicon substrate; and one or more through-silicon vias in the silicon substrate, wherein the one or more through-silicon vias electrically couple at least one of the PIC or the EIC to the package substrate.

Example 13 includes the microelectronic assembly of any of Examples 10-12, wherein the one or more optical waveguides are at least partially on a surface of the glass substrate.

Example 14 includes the microelectronic assembly of any of Examples 10-13, wherein the PIC and the EIC are respectively coupled to the glass substrate via a hybrid dielectric and metal bond.

Example 15 includes the microelectronic assembly of any of Examples 10-14, further comprising a fiber array unit (FAU), wherein the FAU is optically coupled to the one or more optical waveguides, and wherein the FAU and the PIC are optically coupled to each other via the one or more optical waveguides.

Example 16 includes the microelectronic assembly of any of Examples 10-15, further comprising: an optical interface, wherein the optical interface comprises the PIC and the EIC; and an integrated circuit (IC) die electrically coupled to the optical interface, wherein the IC die is to communicate optically via the optical interface, and wherein the IC die comprises processing circuitry, memory circuitry, storage circuitry, or communication circuitry.

Example 17 includes the microelectronic assembly of any of Examples 10-16, wherein the microelectronic assembly is comprised in a mobile device, a wearable device, a computer, a server, a video playback device, a video game console, a display device, a camera, or an appliance.

Example 18 includes a system, comprising: a circuit board; and an integrated circuit (IC) package electrically coupled to the circuit board, wherein the IC package comprises an optical interface, wherein the optical interface comprises: an interposer comprising a glass substrate and a bridge die, wherein the glass substrate comprises one or more optical waveguides, wherein the bridge die comprises one or more conductive traces, and wherein the bridge die is embedded in the glass substrate; a photonic integrated circuit (PIC) coupled to the interposer, wherein the PIC is optically coupled to the one or more optical waveguides, and wherein the PIC is electrically coupled to the bridge die; and an electronic integrated circuit (EIC) coupled to the interposer, wherein the EIC is electrically coupled to the bridge die, and wherein the EIC and the PIC are electrically coupled to each other via the one or more conductive traces in the bridge die.

Example 19 includes the system of Example 18, further comprising a fiber array unit (FAU), wherein the FAU is optically coupled to the PIC via the one or more optical waveguides.

Example 20 includes the system of any of Examples 18-19, further comprising an integrated circuit (IC) die electrically coupled to the optical interface, wherein the IC die is to communicate optically via the optical interface, and wherein the IC die comprises processing circuitry, memory circuitry, storage circuitry, or communication circuitry.

Example 21 includes the system of any of Examples 18-20, wherein the system is a mobile device, a wearable device, a computer, a server, a video playback device, a video game console, a display device, a camera, or an appliance.

Example 22 includes a method, comprising: receiving a glass substrate; forming one or more through-glass vias in the glass substrate; forming a cavity in the glass substrate; embedding a bridge die in the cavity of the glass substrate; forming one or more optical waveguides in the glass substrate; and attaching a plurality of integrated circuit (IC) dies to the glass substrate, wherein the IC dies are electrically coupled to each other via the bridge die, and wherein at least one of the IC dies is optically coupled to the one or more optical waveguides.

Example 23 includes the method of Example 22, wherein at least one of the IC dies comprises a photonic integrated circuit (PIC) and at least one of the IC dies comprises an electronic integrated circuit (EIC), wherein the PIC and the EIC are electrically coupled via the bridge die, and wherein the PIC is optically coupled to the one or more optical waveguides.

Example 24 includes the method of any of Examples 22-23, further comprising attaching a fiber array unit (FAU) to the glass substrate, wherein the FAU is optically coupled to the one or more optical waveguides.

Example 25 includes the method of any of Examples 22-24, further comprising: before embedding the bridge die in the cavity of the glass substrate, placing the glass substrate on a carrier substrate; and after embedding the bridge die in the cavity of the glass substrate, removing the carrier substrate from the glass substrate.

Example 26 includes the method of any of Examples 22-25, further comprising attaching the glass substrate to a package substrate.

1. A semiconductor device, comprising:
a glass substrate comprising one or more optical waveguides; and
a bridge die embedded in the glass substrate, wherein the bridge die comprises an interconnect to electrically couple a plurality of integrated circuit (IC) dies.

2. The semiconductor device of claim 1, wherein the glass substrate further comprises one or more through-glass vias.

3. The semiconductor device of claim 1, wherein:
the bridge die further comprises a silicon substrate; and
the interconnect comprises one or more conductive traces on the silicon substrate.

4. The semiconductor device of claim 3, wherein the interconnect further comprises one or more through-silicon vias in the silicon substrate.

5. The semiconductor device of claim 1, wherein the one or more optical waveguides are at least partially on a surface of the glass substrate.

6. The semiconductor device of claim 1, further comprising the plurality of IC dies, wherein:
the plurality of IC dies include a photonic integrated circuit (PIC) and an electronic integrated circuit (EIC);
the PIC and the EIC are coupled to the glass substrate;
the PIC and the EIC are electrically coupled to each other via the interconnect in the bridge die; and
the PIC is optically coupled to the one or more optical waveguides.

7. The semiconductor device of claim 6, further comprising one or more optical fibers, wherein the one or more optical fibers are optically coupled to the one or more optical waveguides, and wherein the one or more optical fibers and the PIC are optically coupled via the one or more optical waveguides.

8. The semiconductor device of claim 6, wherein the PIC and the EIC are respectively coupled to the glass substrate via a hybrid dielectric and metal bond.

9. The semiconductor device of claim 1, wherein the semiconductor device is:
an optical and electrical interposer;
an optical interface; or
an IC package comprising an optical interface.

10. A microelectronic assembly, comprising:
a package substrate;
an interposer coupled to the package substrate, wherein the interposer comprises:
a glass substrate comprising one or more optical waveguides; and
a bridge die embedded in the glass substrate, wherein the bridge die comprises one or more conductive traces;
a photonic integrated circuit (PIC) coupled to the interposer, wherein the PIC is optically coupled to the one or more optical waveguides, and wherein the PIC is electrically coupled to the bridge die; and
an electronic integrated circuit (EIC) coupled to the interposer, wherein the EIC is electrically coupled to the bridge die, and wherein the EIC and the PIC are electrically coupled to each other via the one or more conductive traces in the bridge die.

11. The microelectronic assembly of claim 10, wherein the glass substrate further comprises one or more through-glass vias, wherein the one or more through-glass vias electrically couple at least one of the PIC or the EIC to the package substrate.

12. The microelectronic assembly of claim 10, wherein the bridge die further comprises:
a silicon substrate, wherein the one or more conductive traces are on the silicon substrate; and
one or more through-silicon vias in the silicon substrate, wherein the one or more through-silicon vias electrically couple at least one of the PIC or the EIC to the package substrate.

13. The microelectronic assembly of claim 10, wherein the one or more optical waveguides are at least partially on a surface of the glass substrate.

14. The microelectronic assembly of claim 10, wherein the PIC and the EIC are respectively coupled to the glass substrate via a hybrid dielectric and metal bond.

15. The microelectronic assembly of claim 10, further comprising a fiber array unit (FAU), wherein the FAU is optically coupled to the one or more optical waveguides, and wherein the FAU and the PIC are optically coupled to each other via the one or more optical waveguides.

16. The microelectronic assembly of claim 10, further comprising:
an optical interface, wherein the optical interface comprises the PIC and the EIC; and
an integrated circuit (IC) die electrically coupled to the optical interface, wherein the IC die is to communicate optically via the optical interface, and wherein the IC die comprises processing circuitry, memory circuitry, storage circuitry, or communication circuitry.

17. A system, comprising:
a circuit board; and
an integrated circuit (IC) package electrically coupled to the circuit board, wherein the IC package comprises an optical interface, wherein the optical interface comprises:
an interposer comprising a glass substrate and a bridge die, wherein the glass substrate comprises one or more optical waveguides, wherein the bridge die comprises one or more conductive traces, and wherein the bridge die is embedded in the glass substrate;
a photonic integrated circuit (PIC) coupled to the interposer, wherein the PIC is optically coupled to the one or more optical waveguides, and wherein the PIC is electrically coupled to the bridge die; and
an electronic integrated circuit (EIC) coupled to the interposer, wherein the EIC is electrically coupled to the bridge die, and wherein the EIC and the PIC are electrically coupled to each other via the one or more conductive traces in the bridge die.

18. The system of claim 17, further comprising a fiber array unit (FAU), wherein the FAU is optically coupled to the PIC via the one or more optical waveguides.

19. The system of claim 17, further comprising an integrated circuit (IC) die electrically coupled to the optical interface, wherein the IC die is to communicate optically via the optical interface, and wherein the IC die comprises processing circuitry, memory circuitry, storage circuitry, or communication circuitry.

20. The system of claim 17, wherein the system is a mobile device, a wearable device, a computer, a server, a video playback device, a video game console, a display device, a camera, or an appliance.
